(19) United States
(12) Patent Application Publication
(10) Pub. No.: US 2006/0261862 A1
(43) Pub. Date: Nov. 23, 2006

(54) Apparatus and method for preventing static current leakage when crossing from a low voltage domain to a high voltage domain

(76) Inventors: Frank Baszler, Ft. Collins, CO (US); David Balhiser, Ft. Collins, CO (US)

Correspondence Address: AVAGO TECHNOLOGIES, LTD., P.O. BOX 1920, DENVER, CO, 80201-1920, US

(21) Appl. No.: 11/135,182

(22) Filed: May 23, 2005

(51) Int. Cl. H03B 1/00

(52) U.S. Cl. 327/108; 327/333

(57) ABSTRACT

A voltage domain transition buffer is presented for transitioning an input data signal from a first voltage domain to a second voltage domain. The buffer includes a first CMOS inverter followed by a second CMOS inverter. The input to the first CMOS inverter is connected to a buffer input and the output connected to the input of the second CMOS inverter at an intermediate node. The output of the second CMOS inverter is connected to a buffer output and also to the gate of a feedback pull-up PFET that is connected in source-drain relationship between the voltage source of the second voltage domain and the intermediate node. A resistive device such as a resistor or NFET is connected between the voltage source of the second voltage domain and the source of the first CMOS inverter. The design of the voltage domain transition buffer eliminates or significantly mitigates leakage current during a non-transitioning state.

### BACKGROUND OF THE INVENTION

The present invention relates generally to dual voltage domain CMOS circuitry, and more particularly to a buffer circuit for transitioning a digital signal from a low voltage domain to a high voltage domain with minimum static current leakage.

In integrated circuits, CMOS (complementary metal-oxide semiconductor) technology is the most frequently used component implementation due to its characteristically low power consumption. In this regard, integrated circuit transistors are conventionally fabricated using semiconductor materials such as silicon and germanium that, when “doped” with added impurities, become full-scale conductors of either extra electrons with a negative charge carriers (N-type transistors, or NMOS) or of positive charge carriers (P-type transistors, or PMOS). NMOS transistors are frequently referred to as NMOS Field Effect Transistors, or NFETs. PMOS transistors are frequently referred to as PMOS Field Effect Transistors, or PFETs. In CMOS technology, both types of transistors, NFETs and PFETs, are used in a complementary manner to form a current gate that forms an effective means of electrical control. For example, FIG. 1A illustrates a CMOS inverter that is implemented with an NFET and a PFET stacked between a circuit ground and a voltage source V_{DD}. As shown in FIG. 1C, CMOS transistors use almost no power when in a stable state, also referred to as a “quiescent” state. In the quiescent state, only a very small amount of current I_{DDQ}_{_{—}}_{GOOD} flows relative to the amount of current flowing during full conduction of the transistor. This small amount of current is referred to as “leakage” current (I_{DDQ}_{_{—}}_{GOOD}).

Generally speaking, a CMOS transistor will conduct current (other than leakage current) only during state transitions, also illustrated in FIG. 1C. Since, in general, CMOS gates are designed to spend the bulk of their time in a stable state, the overall power consumption of a given integrated circuit can therefore typically be minimized using a CMOS implementation of the circuitry. It is because of this property that integrated circuits are most often designed using CMOS technology. It is clear from the above discussion that power consumption in CMOS devices is heavily dependent on the amount of overall leakage current and switching current during the operation of the device.

Implementation of integrated circuits using CMOS technology also has the added benefit of inherent testability. The advantageous characteristic of CMOS implementation, that a CMOS circuit conducts very little current (i.e., only the leakage current) when in a stable state, may be exploited for testing purposes. In this regard, if a known good CMOS circuit results in a known leakage current, it can be inferred that a CMOS circuit fabricated according to the same process that results in increased leakage current is defective. For example, using the example CMOS inverter circuit of FIG. 1A and its resulting quiescent current I_{DDQ}_{_{—}}_{GOOD} shown in FIG. 1C, if a defect exists in the inverter as in the example of FIG. 1B, then the resulting quiescent current I_{DDQ}_{_{—}}_{DEFECT} of the defective circuit is increased over that of the good circuit of FIG. 1A, as illustrated in FIG. 1C.

One test technique that utilizes this theory is known in the art as “IDDQ” testing. IDDQ testing validates CMOS circuits by measuring and observing their quiescent supply current. As stated above, in a quiescent state, only the leakage current flows. The fact that under certain conditions a significant increase in current flow is observed when the device under test is in a quiescent state indicates the presence of a manufacturing defect in the circuit. Such a defect may have a direct influence on the functionality of the circuit (functional failure) or may affect the lifetime and reliability of the circuit negatively ((early) lifetime failure). Because IDDQ testing is able to detect such problems in an early stage (even before they really harm the circuit), and its flexibility in application at the wafer level, package level, during incoming inspection, during life tests or even during on-line testing, IDDQ testing is very common in the industry to guarantee the quality and reliability of the CMOS integrated circuit.

Much research has been invested into the study of leakage current of CMOS devices, both from the perspective of reducing leakage current for power consumption purposes and for determining the quiescent current levels and IDDQ test thresholds (pass/fail thresholds). One complicating factor results from CMOS devices with more than one voltage domain. For example, dual voltage domain devices are now common. In this regard, as the industry trend continues to simultaneously increase the number of components on a given IC and reduce the process size, techniques for addressing power and speed needs have been developed. For instance, a dual voltage domain is often implemented in CMOS integrated circuits—a lower voltage source domain used for the functional core of the device, and a higher voltage source domain used for I/O and communication drivers of the device for interfacing with external components. While a given higher voltage domain is typically required to drive signals of sufficient power to interface properly with external components, use of a lower voltage domain for the functional core is advantageous in that it not only reduces the power consumption for functional operation of the device, but it also allows higher speed operation since a lower voltage swing is required to change states and the gate insulator can be thinned, increasing the electric field of the field effect transistor. Accordingly, such dual voltage domain devices are now ubiquitous.

However, multiple voltage domain devices are problematic for analysis of current leakage. In devices that require digital signals to pass between voltage domains, a voltage domain transition buffer is required to transform the data signal from the first voltage domain (e.g., one sourced by a first power source V_{DD1}) to the second voltage domain (e.g., one sourced by a second power source V_{DD2}). FIG. 2A illustrates a conventional voltage domain transition buffer 10. As shown, an input signal IN existing on the buffer input 12 exists in the first voltage domain, which may be connected to component(s) 2 sourced by the first voltage source V_{DD1} and connected to component(s) 4 connected to the second voltage source V_{SS}. The output signal OUT on the buffer output 16 exists in a second voltage domain, which may be connected to component(s) 6 sourced by a second voltage source V_{DD2} and connected to component(s) 4 connected to the second voltage source V_{SS}. The first voltage source V_{DD1} and the second voltage source V_{DD2} have different potentials, preferably wherein V_{DD2}>V_{DD1}+Vₜ, where Vₜ is the threshold voltage of the CMOS FETs.

The voltage domain transition buffer 10 itself comprises a first CMOS inverter 30 followed by a second CMOS inverter 40. The input of the first CMOS inverter 30 is connected to the buffer input 12 and its output is connected to the input of the second CMOS inverter 40 at an intermediate node 14. The output of the second CMOS inverter 40 is connected to the buffer output 16.

Each of the first and second CMOS inverters 30, 40 respectively comprises a PFET 32, 42 and an NFET 34, 44. In the input CMOS inverter 30, the respective NFET 34 is electrically coupled in a source-drain relationship between the intermediate node 14 and a node 20 that is electrically coupled to a low voltage source V_{SS} 28 (e.g., a circuit ground). The respective PFET 32 is electrically coupled in a drain-source relationship between the intermediate node 14 and a node 22. Node 22 is electrically coupled to the second voltage source V_{DD2} 26. The gates of the PFET 32 and the NFET 34 are connected together at the input node 12. The drain of the PFET 32 and the source of the NFET 34 are connected together at the intermediate node 14.

In the output CMOS inverter 40, the respective NFET 44 is electrically coupled in a source-drain relationship between the output node 16 and a node 21 that is electrically coupled to a low voltage source V_{SS} 28. The respective PFET 42 is electrically coupled in a drain-source relationship between the output node 16 and a node 24 that is coupled to the second voltage source V_{DD2} 26. The gates of the PFET 42 and the NFET 44 are connected together at the intermediate node 14. The drain of the PFET 42 and the source of the NFET 44 are connected together at the output node 16.

In operation, when the input signal IN on node 12 is logic low (e.g., 0 Volts), NFET 34 of the input inverter 30 is operating in the cut-off region, preventing current flow from the intermediate node 14 to V_{SS}, while PFET 32 is operating in the saturation region, which thereby drives the intermediate node 14 to the full logic high (e.g., to rail V_{DD2}). As the intermediate node 14 rises above Vₜ, the NFET 44 of the output inverter 40 transitions into the saturation region, draining the current from the output node 16. When the intermediate node 14 rises to within V_{DD2}−Vₜ, the PFET 42 of the output inverter 40 enters the cut-off region, turning off current flow from the power source V_{DD2} to the output node 16. Since there is no current flow between the power sources V_{DD2} and V_{SS}, there is no leakage current.

However, when the input signal IN on the input node 12 transitions from low to high, this is not the case. When the input signal IN on the input node rises above Vₜ, the NFET 34 of the input inverter transitions into the saturation region, draining the current from the intermediate node 14, which in turn fully turns on the PFET 42 and fully turns off the NFET 44 of the output inverter 40. However, when the input signal IN on the input node 12 reaches its full logic high (e.g., V_{DD1}), the gate-to-source voltage V_{GS} will not get above V_{DD2}−Vₜ, and therefore the PFET 32 will not fully turn off. Accordingly, in this state, a path exists between the power sources V_{DD2} and V_{SS} through PFET 32 and NFET 34, and therefore there is some leakage current.

FIG. 2B is a graphic simulation illustrating the effect on the leakage current (e.g., the current flow from the supply source V_{DD2} to the low voltage source V_{SS} (e.g., ground) of the buffer 10, for the electrical specifications given in TABLE 1.

TABLE 1

| | |
|---|---|
| V_{DD1} | 0.6 Volts |
| V_{DD2} | 1.0 Volts |
| V_{SS} | 0.0 Volts |
| PFET 32 | 8.680 um/0.1 um |
| NFET 34 | 3.140 um/0.12 um |
| PFET 42 | 8.680 um/0.1 um |
| NFET 42 | 3.140 um/0.12 um |
| Effective Process Length | 90 nm |

As illustrated in the upper graph in FIG. 2B, the input data signal IN presented to the buffer input 12 swings from a low voltage V_{SS} (0 Volts) to the first high voltage source V_{DD1}(0.6 Volts). The output data signal OUT generated on the buffer output 16 swings from a low voltage rail of V_{SS} volts to a second high voltage rail of V_{DD2} volts (1.0 Volts). As illustrated in the lower graph in FIG. 2B, the leakage current spikes as expected at the switching transitions, which correspond to the inverters switching states. However, while the input data signal IN is in a logical high state, the input inverter PFET 32 is on at the same time that the input inverter NFET 34 is on, providing a current path between the high voltage source V_{DD2} and the low voltage V_{SS}. This results in a significant leakage current of nearly 200 uAmps.

It would therefore be desirable to eliminate this increase, both from the power consumption perspective and from the IDDQ testing perspective (for ease in determining the quiescent current in either domain). Accordingly, it would be desirable to allow a digital signal to be passed from one voltage domain to a higher voltage domain without a static current.

### SUMMARY OF THE INVENTION

A voltage domain transition buffer is presented which allows transitioning an input signal from a first voltage domain to a second voltage domain without static current. The buffer includes a first CMOS inverter followed by a second CMOS inverter. The input to the first CMOS inverter is connected to a buffer input and the output connected to the input of the second CMOS inverter at an intermediate node. The output of the second CMOS inverter is connected to a buffer output and also to the gate of a feedback pull-up PFET that is connected in source-drain relationship between the voltage source of the second voltage domain and the intermediate node. A resistive device such as a resistor or FET is connected between the voltage source of the second voltage domain and the source of the first CMOS inverter. The voltage domain transition buffer eliminates static current due to the transition of a digital data signal from the first voltage domain to the second voltage domain.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1A is a schematic diagram of a conventional CMOS inverter with no defects;

FIG. 1B is a schematic diagram of the conventional CMOS inverter of FIG. 1A with a manufacturing defect;

FIG. 1C is a waveform diagram illustrating the quiescent current of both the good CMOS inverter device of FIG. 1A and the defective CMOS inverter device of FIG. 1B plotted over time;

FIG. 2A is a schematic diagram of a conventional voltage domain transitioning buffer used in a dual-voltage-domain device;

FIG. 2B shows graphical waveform diagrams illustrating the leakage current of the voltage domain transitioning buffer of FIG. 2A based on input signal voltage changes for an example simulated implementation;

FIG. 3A is a schematic diagram of a first voltage domain transitioning buffer implemented in accordance with the invention;

FIG. 3B shows graphical waveform diagrams illustrating the leakage current of the voltage domain transitioning buffer of FIG. 3A based on input signal voltage changes for an example simulated implementation;

FIG. 4A is a schematic diagram of a second voltage domain transitioning buffer implemented in accordance with the invention; and

FIG. 4B shows graphical waveform diagrams illustrating the leakage current of the voltage domain transitioning buffer of FIG. 4A based on input signal voltage changes for an example simulated implementation.

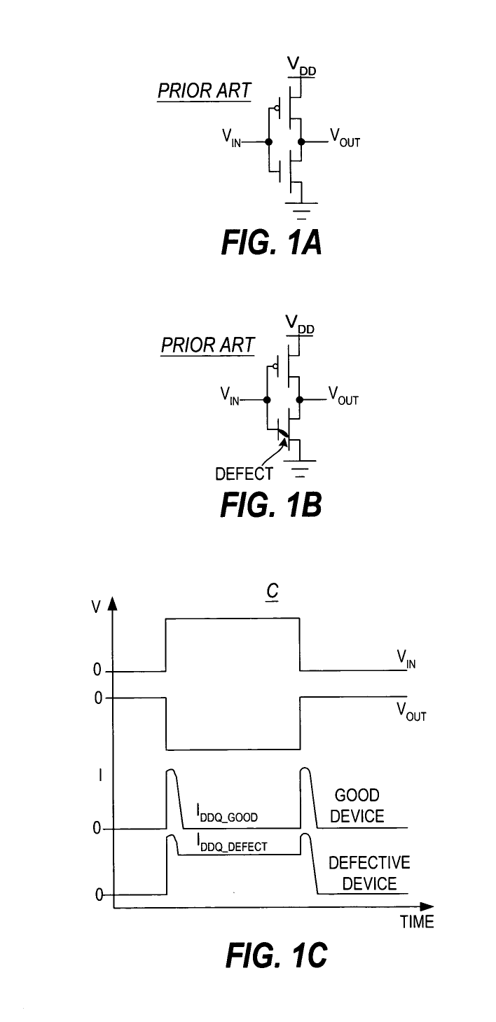

### DETAILED DESCRIPTION

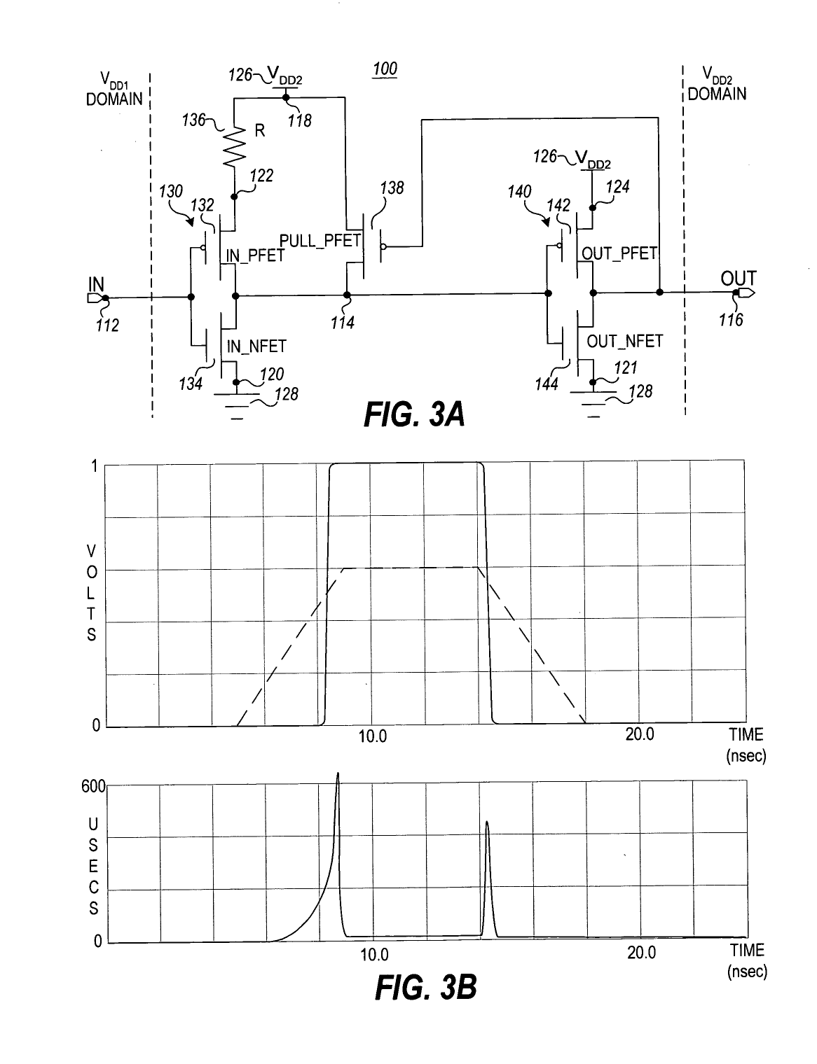

Turning now to the invention, FIG. 3A is a schematic diagram of a preferred embodiment of a voltage domain transition buffer 100 implemented in accordance with the invention. As shown therein, the buffer includes a buffer input 112 on which an input signal IN is received, and a buffer output 116 on which an output signal OUT is generated. The input signal IN on the buffer input 112 exists in a first voltage domain, sourced by a first voltage source V_{DD1}, while the output signal OUT on the buffer output 116 exists in a second voltage domain, sourced by a second voltage source V_{DD2}. The first voltage source V_{DD1} is preferably lower in voltage than the second voltage source V_{DD2}.

The voltage domain transition buffer 100 itself comprises a first CMOS inverter 130 having an input connected to the buffer input 112 and an output connected to an intermediate node 114, followed by a second CMOS inverter 140 having an input connected to the intermediate node 114 and an output connected to the buffer output 16. The voltage domain transition buffer 100 also comprises a resistor 136 (labeled R) and a pull-up PFET 138 (labeled PULL_PFET), discussed hereinafter.

Each of the first and second CMOS inverters 130, 140 respectively comprises a PFET 132, 142 (respectively labeled IN_PFET and OUT_PFET) and an NFET 134, 144 (respectively labeled IN_NFET and OUT_NFET). In the input CMOS inverter 130, the respective NFET 134 is electrically coupled in a source-drain relationship between the intermediate node 114 and a node 120 that is electrically coupled to a low voltage source V_{SS} 128 (e.g., a circuit ground). The respective PFET 132 is electrically coupled in a drain-source relationship between the intermediate node 114 and a node 122. Node 122 is coupled through resistor R 136 to a node 118 that is electrically coupled to the second voltage source V_{DD2} 126. The gates of the PFET 132 and the NFET 134 are connected together at the input node 112. The drain of the PFET 132 and the source of the NFET 134 are connected together at the intermediate node 114.

In the output CMOS inverter 140, the respective NFET 144 is electrically coupled in a source-drain relationship between the output node 116 and a node 121 that is electrically coupled to the low voltage source V_{SS} 128. The respective PFET 142 is electrically coupled in a drain-source relationship between the output node 116 and a node 124 that is coupled to the second voltage source V_{DD2} 126. The gates of the PFET 142 and the NFET 144 are connected together at the intermediate node 114. The drain of the PFET 142 and the source of the NFET 144 are connected together at the output node 116.

The pull-up PFET 138 is electrically coupled in source-drain relationship between the node 118 (which is coupled to the second voltage source V_{DD2} 126) and the intermediate node 114. The gate of the pull-up PFET 138 is electrically coupled to the output node 116.

An input data signal IN presented to the buffer input 112 swings from a low voltage V_{SS} to the first high voltage source V_{DD1}. The output data signal OUT generated on the buffer output 116 swings from a low voltage rail of V_{SS} volts to a second high voltage rail of V_{DD2} volts, preferably where V_{DD2}>V_{DD1}+Vₜ. Typically, the low voltage source V_{SS} is the circuit ground so the low voltage rail V_{SS} is 0 volts. Logical 0, or “low”, is herein considered to be V_{SS} volts and logical 1, or “high”, is V_{DD1} volts in the first voltage domain and V_{DD2} in the second voltage domain.

In operation, when the input data signal IN is a logical 0, the input inverter NFET 134 (In_NFET) operates in the cut-off region and does not conduct, and the input inverter PFET 132 (In_PFET) operates in the saturation region, thereby conducting current from the second voltage source V_{DD2} 126 through resistor R 136 to the intermediate node 114. The voltage on the intermediate node 114 rises to a level that will enable current flow on the output inverter NFET 144 (Out_NFET) while simultaneously reducing current flow from the second voltage source V_{DD2} 126 through the output buffer PFET 142 (Out_PFET) onto the output node 116. This voltage of the output signal OUT will therefore be driven toward V_{SS} volts; however, because the voltage drop across the resistor R 136 reduces the voltage at node 122 to less than or equal to the first voltage source rail, V_{DD1}, although the PFET 132 in the input inverter will enter the cut-off region since the input signal will come within Vₜ of the node 122, the PFET 142 in the output inverter will not enter the cut-off region. Therefore, due to leakage current in the output inverter, the output signal OUT will only approach V_{SS} volts and cannot reach it completely. However, as the output signal OUT approaches V_{SS} volts, it enables the pull-up PFET 138 (Pull_PFET) to begin conducting and to pull up the voltage of the intermediate node 114 to the full second voltage rail V_{DD2}. As a result, the leakage current will stabilize at 0 Amps.

When the input signal IN is a logical 1, the input inverter PFET 132 (In_PFET) operates in the cut-off region because the voltage drop across the resistor R 136 reduces the voltage at node 122 to less than or equal to the first voltage source rail, V_{DD1}. As the input signal IN rises above Vₜ, the input inverter NFET 134 (In_NFET) transitions to the saturation region, draining the voltage on the intermediate node 114 to the full low voltage rail, V_{SS}. As the voltage on the intermediate node 114 decreases below V_{DD2}−Vₜ towards V_{SS}, the output inverter PFET 142 (Out_PFET) will transition to the saturation region, while simultaneously pinching off current flow through the output buffer NFET 144 (Out_NFET). The voltage level of the output signal OUT will therefore begin to rise, pinching off current flow through the pull-up PFET 138 along its ascent and ultimately rising to the second voltage rail V_{DD2}. As a result, the leakage current will again stabilize at 0 Amps.

TABLE 2 lists the FET sizes and resistor values of an example implementation of the buffer 100 of FIG. 3A, and FIG. 3B illustrates simulated waveforms for this particular implementation.

TABLE 2

| | |
|---|---|
| V_{DD1} | 0.6 Volts |
| V_{DD2} | 1.0 Volts |
| V_{SS} | 0.0 Volts |
| PFET 132 | 8.680 um/0.1 um |
| NFET 134 | 3.140 um/0.12 um |
| PFET 142 | 8.680 um/0.1 um |
| NFET 142 | 3.140 um/0.12 um |
| PFET 138 | 2.170 um/0.1 um |
| R | 10 KOhms |
| Effective Process Length | 90 nm |

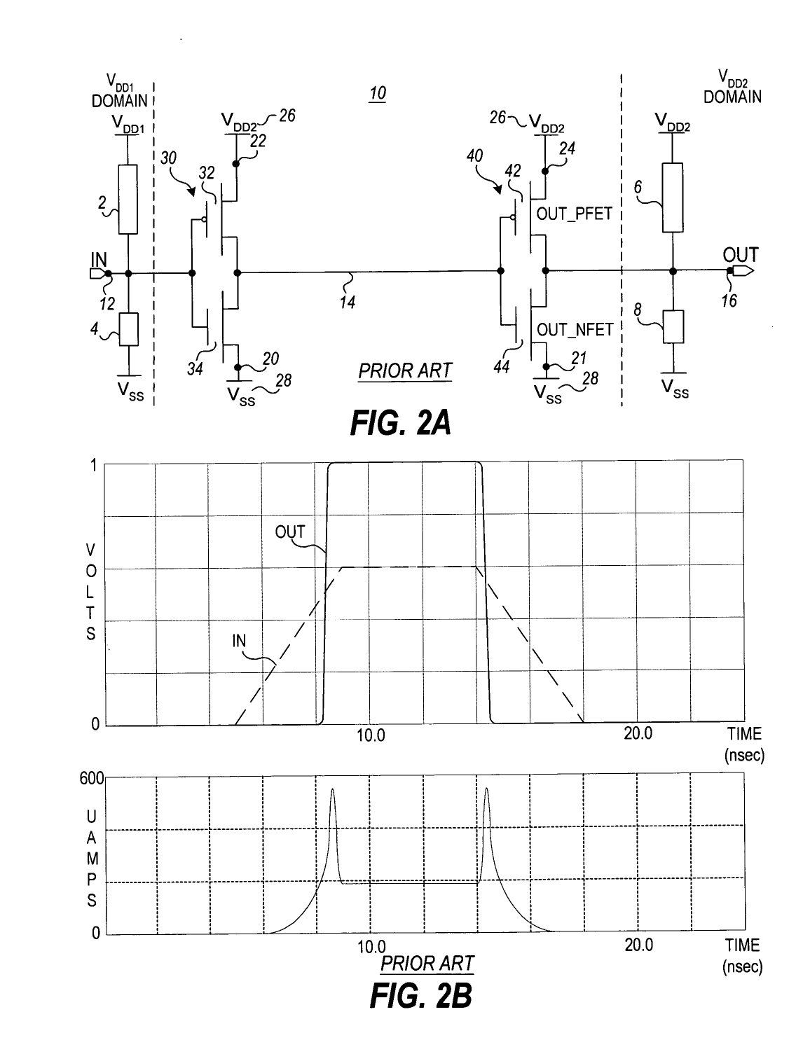

As illustrated in FIG. 3B, the switching current spikes are expected at the edge transitions of the input data signal IN. However, unlike the prior art buffer 10 of FIG. 2A, there is no significant leakage current in either stable state of the input data signal IN.

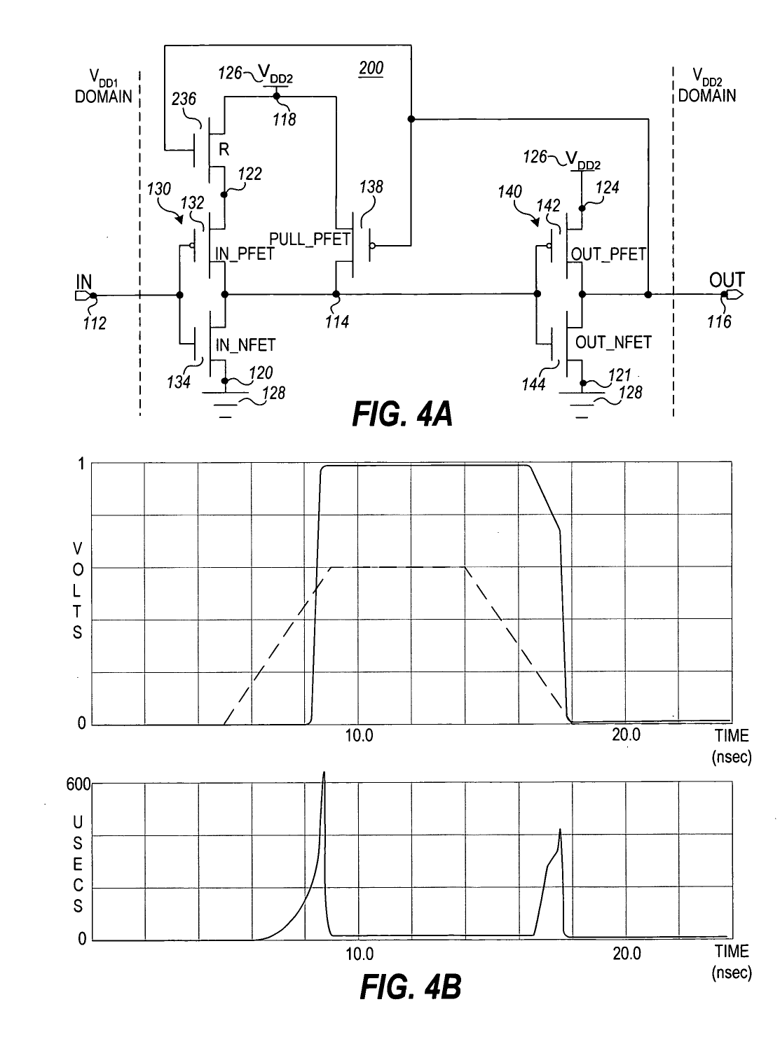

FIG. 4A is a schematic diagram of an alternative preferred embodiment of a voltage domain transition buffer 200 implemented in accordance with the invention. The implementation is similar to that of FIG. 3A, but utilizes an NFET 236 in place of the resistor R 136 of FIG. 2A. In this embodiment, the NFET 236 is sourced by the second voltage source V_{DD2} 126 and has its drain connected to node 122 feeding the source of the input inverter PFET 132. The gate of the NFET 236 (along with the gate of the pull-up PFET 138) is connected to the output node 116 and is therefore driven by the output data signal OUT. In all other respects, the circuit is identical to that of FIG. 3A, and therefore like components are identified with the same reference number.

In operation, when the input data signal IN is a logical 0, the input inverter NFET 134 (In_NFET) operates in the cut-off region and does not conduct, while the input inverter PFET 132 (In_PFET) operates in the saturation region, thereby conducting current from the node 122 to the intermediate node 114. The node 122 initially has a voltage of V_{DD2}−Vₜ (precharged from the previous output state change), thereby supplying current through the input inverter PFET 132 to drive the intermediate node high. The voltage on the intermediate node 114 rises above Vₜ and continues rising, which causes the output inverter NFET 144 to transition from operating in the cut-off region to operating in the saturation region while simultaneously pinching the flow of current through the output buffer PFET 142 to reduce current flow to the output node 116 from the second voltage source V_{DD2} 126 through the output buffer PFET 142. The output signal OUT will therefore be driven toward V_{SS} volts; however, because the voltage drop across the NFET 236 reduces the voltage at node 122 to less than or equal to V_{DD2}−Vₜ, the voltage on the intermediate node 114 cannot (without additional assistance, as described hereinafter) reach the level of V_{DD2}−Vₜ or above that would allow the output inverter PFET 142 to operate in the cut-off region and thereby prevent current flow therethrough. However, the output inverter NFET 144 is sized to drive stronger than the output inverter FET 142, and therefore the output signal OUT will decrease, approaching V_{SS} volts. As the output signal OUT approaches V_{SS} volts, it enables the pull-up PFET 138 (Pull_PFET) to begin conducting and to pull up the voltage of the intermediate node 114 to the full second voltage rail V_{DD2}. As a result, the output inverter PFET 142 will enter the cut-off region of operation, and the leakage current will stabilize at 0 Amps.

When the input signal IN transitions to a logical 1, the voltage on input node 112 rises above Vₜ, and ascends, causing the input inverter NFET 134 to transition from operation in the cut-off region to operation in the saturation region to pull the voltage of the intermediate node 114 to the full low voltage rail, V_{SS}. The voltage drop across NFET 236 results in a voltage on node 122 as V_{DD2}−Vₜ. Accordingly, as the input signal IN approaches the V_{DD1} rail, this allows current flow through the input inverter PFET 132 to be pinched off and the PFET 132 to operate in the cut-off region. As the voltage on the intermediate node 114 decreases below V_{DD2}−Vₜ towards V_{SS}, the output inverter PFET 142 (Out_PFET) transitions to the saturation region, while simultaneously current flow through the output buffer NFET 144 is pinched off. The voltage level of the output signal OUT will therefore begin to rise. As it rises above Vₜ, the NFET 236 transitions from the cut-off region to the saturation region to drive the node 122 to V_{DD2}−Vₜ, which sources the current driving the intermediate node 114 high though input inverter PFET 132. As the output signal OUT rises above V_{DD2}−Vₜ, the pull-up PFET 138 enters the cut-off region, pinching off current flow to the intermediate node 114 through the pull-up PFET 138 along its ascent. Accordingly, the output signal OUT ultimately rises to the second voltage rail V_{DD2}. As a result, and the leakage current will again stabilize at 0 Amps.

It will be appreciated by those skilled in the art that in the designs of FIGS. 3A and 4A, when intermediate node 114 is driven to V_{SS}, the PFET 142 and NFET 144 of the output inverter 140 operating like a traditional CMOS inverter, and the resistor R 136 or NFET 236 creates a Vₜ, drop in voltage on node 122 that sources the PFET 132, which allows this circuit to work. In effect, the design utilizes the Vₜ drop across R 136 or NFET 236 because V_{DD2}−Vₜ<V_{DD1}, and V_{DD2}>V_{DD1}, and at these small supply voltages this becomes interesting. It will be appreciated that the gate of the NFET 236 could alternatively be connected directly to the high voltage source V_{DD2} or to another node that is driven to V_{DD2}. However, in the preferred embodiment, the gate of the NFET 236 is connected to the output node 116 because tying it to the output signal OUTPUT results in favorable switching behavior since by doing so, in the FET drive fight, the input NFET 134 need only overcome the small pull-up PFET 138 and not the large input inverter PFET 132, thus reducing switch current and time.

TABLE 3 lists the FET sizes and resistor values of an example implementation of the buffer 100 of FIG. 4A, and FIG. 4B illustrates simulated waveforms for this particular implementation.

TABLE 3

| | |
|---|---|
| V_{DD1} | 0.6 Volts |
| V_{DD2} | 1.0 Volts |
| V_{SS} | 0.0 Volts |
| PFET 132 | 8.680 um/0.1 um |
| NFET 134 | 3.140 um/0.12 um |
| PFET 142 | 8.680 um/0.1 um |
| NFET 142 | 3.140 um/0.12 um |
| PFET 138 | 2.170 um/0.1 um |
| NFET 236 | 1.570 um/0.12 um |
| Effective Process Length | 90 nm |

As illustrated in FIG. 4B, the leakage current spikes as expected at the edge transitions of the input data signal IN. However, unlike the prior art buffer 10 of FIG. 2A, there is no significant leakage current in either stable state of the input data signal IN.

It will be clear to those skilled in the art that the sizing of the FETS 132, 134, 138, 142, 144 and value of the resistor R 136 or NFET 236 will affect the parameters and performance of the circuit and will vary from application to application depending on the many parameters of the fabrication process, including semiconductor material and thickness, voltage levels of the various sources (V_{SS}, V_{DD1}, V_{DD2}), desired quiescent current, etc. Accordingly, the designer will have to apply standard design theory when determining these values.

Although this preferred embodiment of the present invention has been disclosed for illustrative purposes, those skilled in the art will appreciate that various modifications, additions and substitutions are possible, without departing from the scope and spirit of the invention as disclosed in the accompanying claims. It is also possible that other benefits or uses of the currently disclosed invention will become apparent over time.

What is claimed is:

1. A voltage domain transition buffer for transitioning an input signal from a first voltage domain that is sourced by a first voltage source to an output signal in a second voltage domain that is sourced by a second voltage source, comprising:
a buffer input on which an input signal is received;
a buffer output on which an output signal is generated;
a first CMOS inverter having an input connected to the buffer input and an output connected to an intermediate node, the first CMOS inverter comprising a first NFET with a first NFET gate electrically coupled to the buffer input and a first PFET with a first PFET gate electrically coupled to the buffer input, wherein the first NFET is electrically coupled in a source-drain relationship between the intermediate node and a low voltage source V_{SS} and the first PFET is electrically coupled in a drain-source relationship between the intermediate node and a source node;
a resistive device coupled between the second voltage source and the source node;
a second CMOS inverter having an input connected to the intermediate node and an output connected to the buffer output, the second CMOS inverter comprising a second NFET with a second NFET gate electrically coupled to the intermediate node and a second PFET with a second PFET gate electrically coupled to the intermediate node, wherein the second NFET is electrically coupled in a source-drain relationship between the buffer output and the low voltage source and the second PFET is electrically coupled in a drain-source relationship between the buffer output and the second voltage source; and
a pull-up PFET with a gate coupled to the buffer output, a source coupled to the second voltage source, and a drain coupled to the intermediate node.

2. The voltage domain transition buffer of claim 1, wherein the low voltage source comprises a circuit ground.

3. The voltage domain transition buffer of claim 2, wherein the first voltage source is lower in voltage than the second voltage source.

4. The voltage domain transition buffer of claim 1, wherein the first voltage source is lower in voltage than the second voltage source.

5. The voltage domain transition buffer of claim 1, wherein the resistive device comprises a resistor coupled between the source node and the second voltage source.

6. The voltage domain transition buffer of claim 5, wherein the low voltage source comprises a circuit ground.

7. The voltage domain transition buffer of claim 6, wherein the first voltage source is lower in voltage than the second voltage source.

8. The voltage domain transition buffer of claim 5, wherein the first voltage source is lower in voltage than the second voltage source.

9. The voltage domain transition buffer of claim 1, wherein the resistive device comprises an NFET coupled in drain-source relationship between the source node and the second voltage source, and having a gate coupled to the buffer output.

10. The voltage domain transition buffer of claim 9, wherein the low voltage source comprises a circuit ground.

11. The voltage domain transition buffer of claim 10, wherein the first voltage source is lower in voltage than the second voltage source.

12. The voltage domain transition buffer of claim 9, wherein the first voltage source is lower in voltage than the second voltage source.

13. A voltage domain transition buffer for transitioning an input signal from a first voltage domain that is sourced by a first voltage source to an output signal in a second voltage domain that is sourced by a second voltage source, comprising:
a buffer input on which an input signal is received;
a buffer output on which an output signal is generated;
a first CMOS inverter having an input connected to the buffer input and an output connected to an intermediate node, the first CMOS inverter comprising a first NFET with a first NFET gate electrically coupled to the buffer input and a first PFET with a first PFET gate electrically coupled to the buffer input, wherein the first NFET is electrically coupled in a source-drain relationship between the intermediate node and a low voltage source Vₛₛ and the first PFET is electrically coupled in a drain-source relationship between the intermediate node and a source node;
a resistor coupled between the source node and the second voltage source;
a second CMOS inverter having an input connected to the intermediate node and an output connected to the buffer output, the second CMOS inverter comprising a second NFET with a second NFET gate electrically coupled to the intermediate node and a second PFET with a second PFET gate electrically coupled to the intermediate node, wherein the second NFET is electrically coupled in a source-drain relationship between the buffer output and the low voltage source and the second PFET is electrically coupled in a drain-source relationship between the buffer output and the second voltage source; and
a pull-up PFET with a gate coupled to the buffer output, a source coupled to the second voltage source, and a drain coupled to the intermediate node.

14. The voltage domain transition buffer of claim 13, wherein the low voltage source comprises a circuit ground.

15. The voltage domain transition buffer of claim 14, wherein the first voltage source is lower in voltage than the second voltage source.

16. The voltage domain transition buffer of claim 13, wherein the first voltage source is lower in voltage than the second voltage source.

17. A voltage domain transition buffer for transitioning an input signal from a first voltage domain that is sourced by a first voltage source to an output signal in a second voltage domain that is sourced by a second voltage source, comprising:
a buffer input on which an input signal is received;
a buffer output on which an output signal is generated;
a first CMOS inverter having an input connected to the buffer input and an output connected to an intermediate node, the first CMOS inverter comprising a first NFET with a first NFET gate electrically coupled to the buffer input and a first PFET with a first PFET gate electrically coupled to the buffer input, wherein the first NFET is electrically coupled in a source-drain relationship between the intermediate node and a low voltage source Vₛₛ and the first PFET is electrically coupled in a drain-source relationship between the intermediate node and a source node;
an NFET coupled in drain-source relationship between the source node and the second voltage source, and having a gate coupled to the buffer output;
a second CMOS inverter having an input connected to the intermediate node and an output connected to the buffer output, the second CMOS inverter comprising a second NFET with a second NFET gate electrically coupled to the intermediate node and a second PFET with a second PFET gate electrically coupled to the intermediate node, wherein the second NFET is electrically coupled in a source-drain relationship between the buffer output and the low voltage source and the second PFET is electrically coupled in a drain-source relationship between the buffer output and the second voltage source; and
a pull-up PFET with a gate coupled to the buffer output, a source coupled to the second voltage source, and a drain coupled to the intermediate node.

18. The voltage domain transition buffer of claim 17, wherein the low voltage source comprises a circuit ground.

19. The voltage domain transition buffer of claim 18, wherein the first voltage source is lower in voltage than the second voltage source.

20. The voltage domain transition buffer of claim 17, wherein the first voltage source is lower in voltage than the second voltage source.
